(19) United States
(12) Patent Application Publication
(10) Pub. No.: US 2015/0361613 A1
(43) Pub. Date: Dec. 17, 2015

(54) METHOD FOR PREPARING AN ELONGATE MATERIAL PROVIDED WITH GRAFTED CARBON NANOSTRUCTURES, AND ASSOCIATED DEVICE AND PRODUCT

(71) Applicant: UNIVERSITE DE HAUTE ALSACE, Mulhouse Cedex (FR)

(72) Inventors: Bernard-Gustave-Camille DURAND, PFASTATT (FR); Fabrice LAURENT, LEIMBACH (FR); Thang LE HUU, MULHOUSE (FR); Jean-Baptiste DONNET, DIDENHEIM (FR)

(21) Appl. No.: 14/759,576

(22) PCT Filed: Jan. 10, 2014
(86) PCT No.: PCT/EP2014/050406

§ 371 Date: Jul. 7, 2015

(30) Foreign Application Priority Data
Jan. 10, 2013 (FR) 1350228

(51) Int. Cl. D06M 11/74; C23C 16/54; C23C 16/26; C23C 16/56

(52) U.S. Cl. CPC D06M 11/74; C23C 16/56; C23C 16/545; C23C 16/26; D06M 2101/40

(57) ABSTRACT

A method includes the following steps: providing a grafting device (20) including a torch (26) that produces a flame (28) in a volume of ambient air and a cooling substrate (33) positioned facing the flame (28); moving the elongate material (14) continuously through the flame (28) between the torch (26) and the cooling substrate (33); and grafting carbon nanostructures (16) continuously onto the elongate material (14) during its passage through the flame (28).

The present invention relates to a method for preparing an elongate material with grafted carbon nanostructures.

Such a method is in particular intended to manufacture products comprising an elongate material in fibrous or solid form, on which carbon nanostructures are grafted, such as carbon nanotubes or carbon nanofibers.

The products obtained using a method according to the invention are functionalized by the presence of grafted carbon nanostructures to modify and improve the properties of the initial elongate material.

The products thus manufactured have different properties from those of the elongate base material, in particular improved mechanical, electrical or chemical properties.

The elongate base material is advantageously a fiber, assembly of fibers such as a thread, or a network of fibers, woven, braided, knitted, or nonwoven. It is preferably able to be wound and unwound from the storage assembly, that assembly being able to be a drum or spool.

A “fiber” is a filamentous substance that may be extruded and/or woven. The fiber may be or animal, plant, artificial, mineral or synthetic origin.

A “thread” is generally a long and thin strand of material, in particular fibers, [or] a meeting of the strands of those materials that have been twisted and extruded.

The threads may be assembled regularly by interlacing to form a fabric, braid or knit.

A nonwoven is generally a sheet or web of natural fibers and/or manufactured fibers or filaments, excluding paper, which have not been woven and which may be bonded to one another in different ways, for example by mechanical assembly (needle punching) or chemical assembly.

Alternatively, the elongate material is a non-fibrous such as a film.

In general, the grafting of carbon nanostructures on fibrous elongate materials is done under a controlled atmosphere in a chemical vapor deposition (CVD) enclosure.

The fibrous elongate material is first de-oiled, then a metal catalyst is deposited on the surface.

The material thus treated is next introduced into a chemical vapor deposition enclosure. This enclosure is for example a tubular quartz furnace swept with a hydrocarbon gas.

Under certain conditions, carbon nanotubes then grow on the surface of the fibrous material, after a time exceeding several tens of minutes, for example comprised between 15 minutes and 60 minutes.

Such a method, for example described in Shaffer et al., Carbon, 48, 277-286, 2010 or in EP 2,254,830, is therefore not very practical to implement industrially. It has a limited productivity and requires a large number of manipulations.

To offset this problem, EP 2,290,139 describes a grafting method in which successive lengths of elongate material are sequentially introduced into a plasma furnace, after treatment of the surface of the elongate material, to create a grafting of carbon nanotubes in the plasma.

Such a method improves the productivity of the grafting, but remains complicated to carry out. In fact, on the one hand, the presence of the plasma furnace requires monitoring of the interface by which the elongate material is inserted into the furnace and complicates the maintenance of a controlled atmosphere in the furnace, and on the other hand, the fiber must be kept at a temperature comprised between 500° C. and 1000° C. before entering the plasma, which complicates control of the process.

One aim of the invention is to obtain a method making it possible to prepare an elongate material provided with grafted carbon nanostructures that is very simple and cost-effective to implement, while producing a high-quality product.

To that end, the invention relates to a method of the aforementioned type, characterized in that it includes the following steps:
providing a grafting device comprising a torch producing a flame in an ambient air volume, and a cooling medium positioned across from the flames;
continuous advancement of the elongated material through the flame between the torch and the cooling support;
continuous grafting of carbon nanostructures on the elongate material as it progresses through the flame.

The method according to the invention may comprise one or more of the following features, considered alone or according to any technically possible combination:
the continuous advancement of the elongate material includes the withdrawal of the raw elongate material outside an upstream withdrawal assembly, the passage of the withdrawn raw elongate material through the flame, then the storage of the elongate material by the carbon nanostructures on a downstream storage assembly;
it includes the passage of the elongate material between a base part of the cooling support and a part opposite the cooling support positioned between the base part and the torch, the base part and the opposite part each being cooled;
the elongate material is pressed against the base part in the flame during its continuous advancement through the flame;
the cooling support includes at least one inclined surface for deflecting at least one main segment of the flame produced by the torch, the flame produced by the torch comprising a deflected segment situated downstream from the inclined deflection surface, the elongate material passing through the deflected segment;
the temperature of the region of the flame in which the elongate material passes is below 700° C., and is in particular comprised between 400° C. and 700° C.;
the torch produces a flame created by the combustion of a hydrocarbon power gas, such as acetylene, with oxygen, the ratio of the flow of power gas to the flow of oxygen provided in the torch advantageously being greater than 1;
it includes a step for deposition on the surface of the elongate material of a catalytic agent able to initiate the growth of carbon nanostructures, the catalytic agent advantageously being deposited from a diluted metal solution;
the speed of advancement of the elongate material in the flame is greater than 1 mm/min, in particular greater than 5 mm/min, advantageously greater than 300 mm/min, and is in particular comprised between 300 mm/min and 10,000 mm/min;
the speed of advancement is greater than 1 m/min, advantageously greater than 3 m/min, in particular greater than 5 m/min.

The invention also relates to an installation for preparing an elongate material provided with grafted carbon nanostructures, characterized in that it comprises:
a grafting device comprising a torch producing a flame in a volume of ambient air, the grafting device including a cooling support positioned across from the flame;
an assembly for continuous advancement of the elongate material through the flame between the torch and the cooling support;
the grafting device being able to continuously graft carbon nanostructures on the elongate material as it advances through the flame.

The installation according to the invention may comprise one or more of the following features, considered alone or according to any technically possible combination:
the assembly for continuous advancement of the elongate material includes an upstream assembly for withdrawal of the raw elongate material, a mechanism for passing the withdrawn raw elongate material through the flame, and a downstream assembly for storage of the elongate material provided with carbon nanostructures;
the cooling support includes a base part and an opposite part positioned between the base part and the torch, the base part and the opposite part each being cooled, the advancement assembly being able to guide the elongate material between the base part and the opposite part;
the cooling support includes at least one inclined deflection surface for at least one main segment of the flame produced by the torch, the flame produced by the torch comprising a deflected segment situated downstream from the inclined deflection surface, the advancement assembly being able to guide the elongate material so that it passes through the deflected segment.

The invention also relates to a product comprising an elongate material provided with grafted carbon nanostructures, in particular carbon nanotubes and/or carbon nanofibers, characterized in that it can be obtained using the method as described above.

The invention will be better understood upon reading the following description, provided solely as an example, and done in reference to the appended drawings, in which:

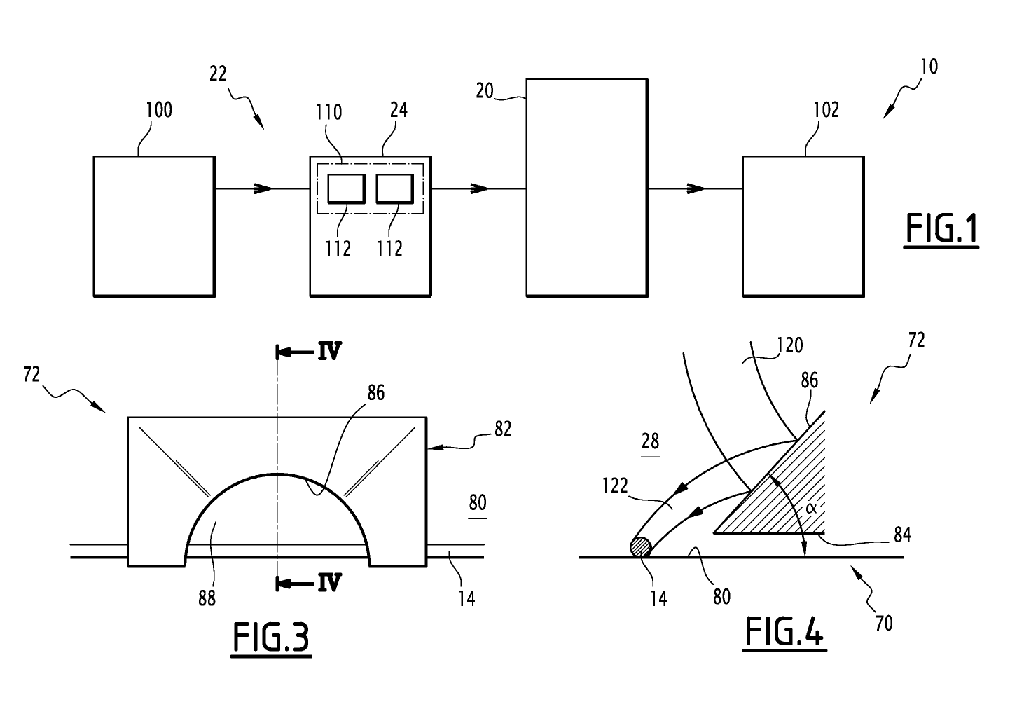

FIG. 1 is a diagrammatic view of a first installation for preparing elongate material provided with grafted carbon nanostructures according to the invention;

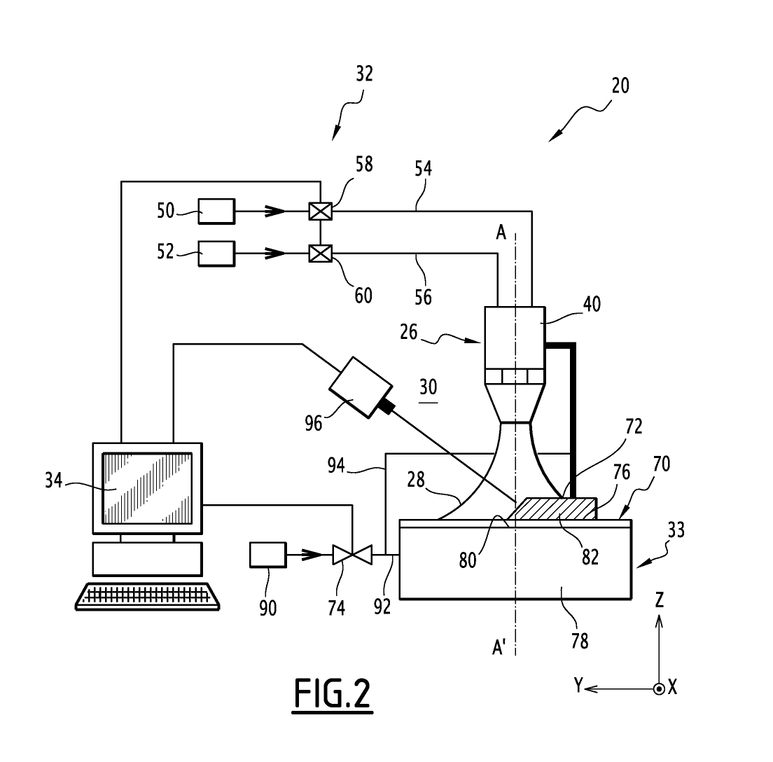

FIG. 2 is a diagrammatic view of the grafting device of the installation of FIG. 1;

FIG. 3 is a partial top view of the cooling support for the elongate material in the grafting device of FIG. 2;

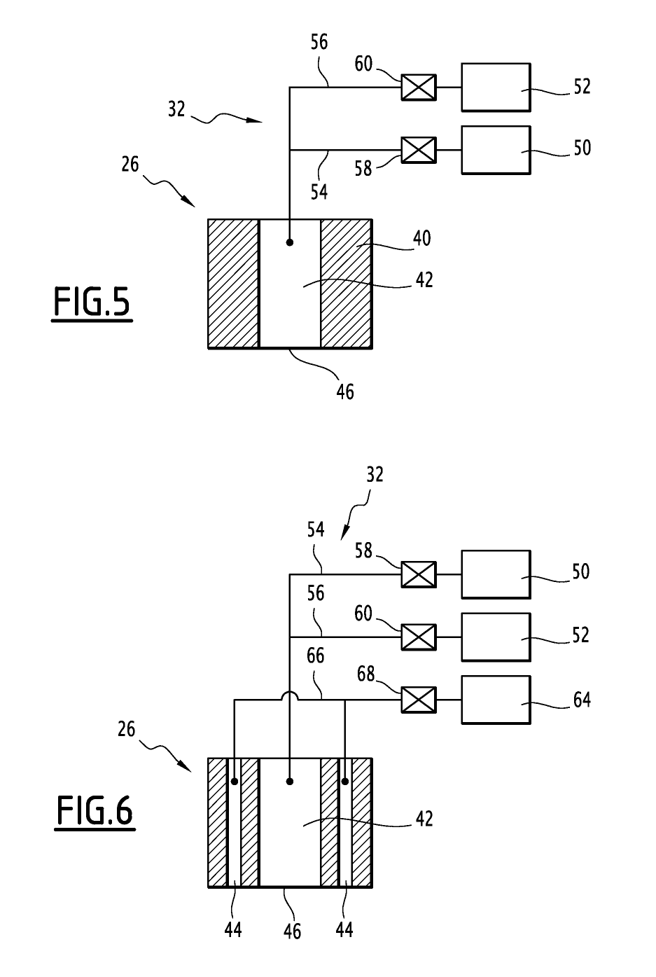

FIG. 4 is a partial sectional view, along plane IV-IV of FIG. 3, illustrating the passage of the elongate material through the flame of the grafting device;

FIG. 5 is a diagrammatic sectional view of a torch of the grafting device of FIG. 2;

FIG. 6 is a view similar to FIG. 5 of another torch for the device of FIG. 2;

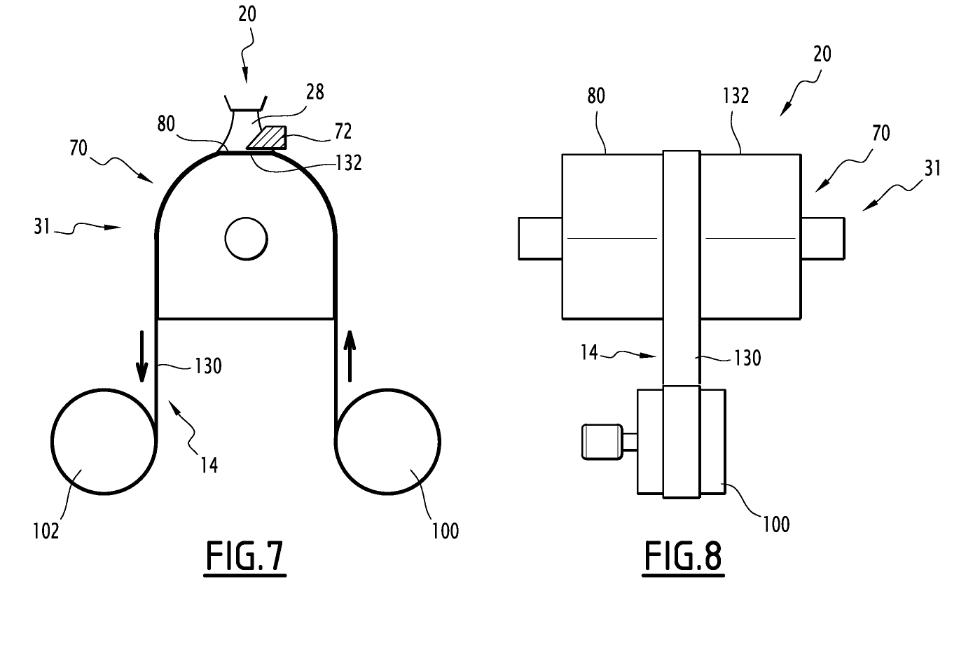

FIG. 7 is a front view of a second grafting device according to the invention for the installation of FIG. 1;

FIG. 8 is a side view of the alternative grafting device of FIG. 7;

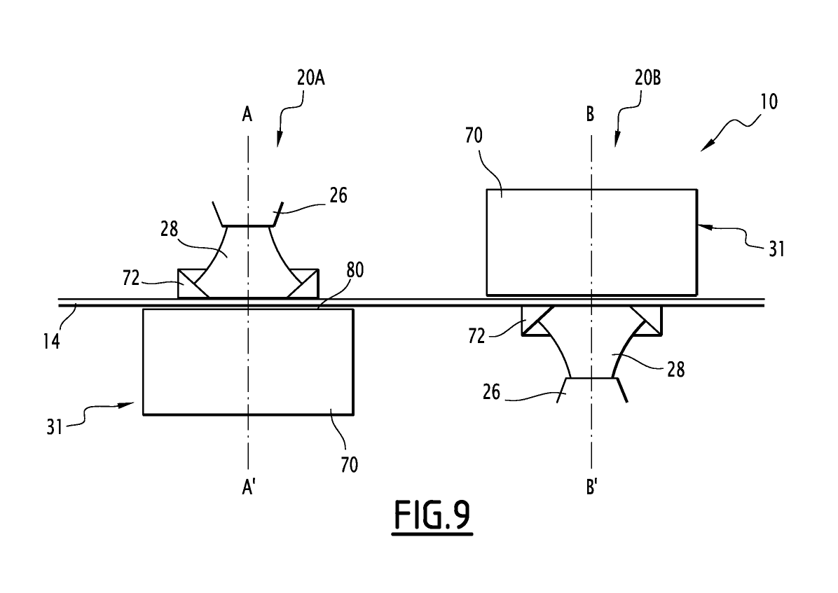

FIG. 9 is a view similar to FIG. 7 of a third grafting device according to the invention;

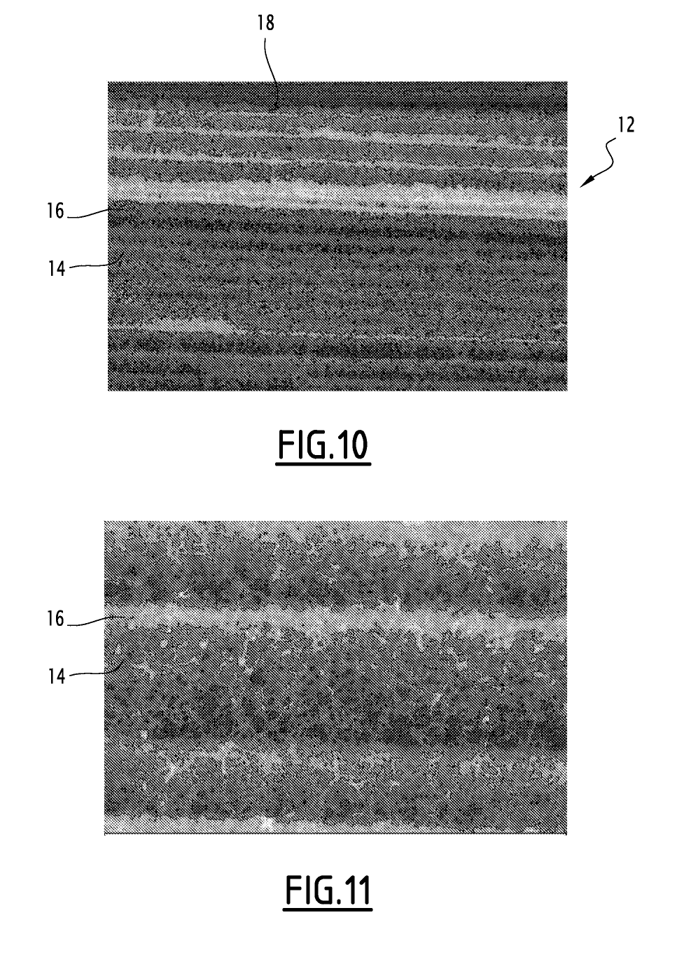

FIG. 10 is a photograph illustrating a product obtained in the preparation installation of FIG. 1;

FIG. 11 is an enlarged view of the product of FIG. 10;

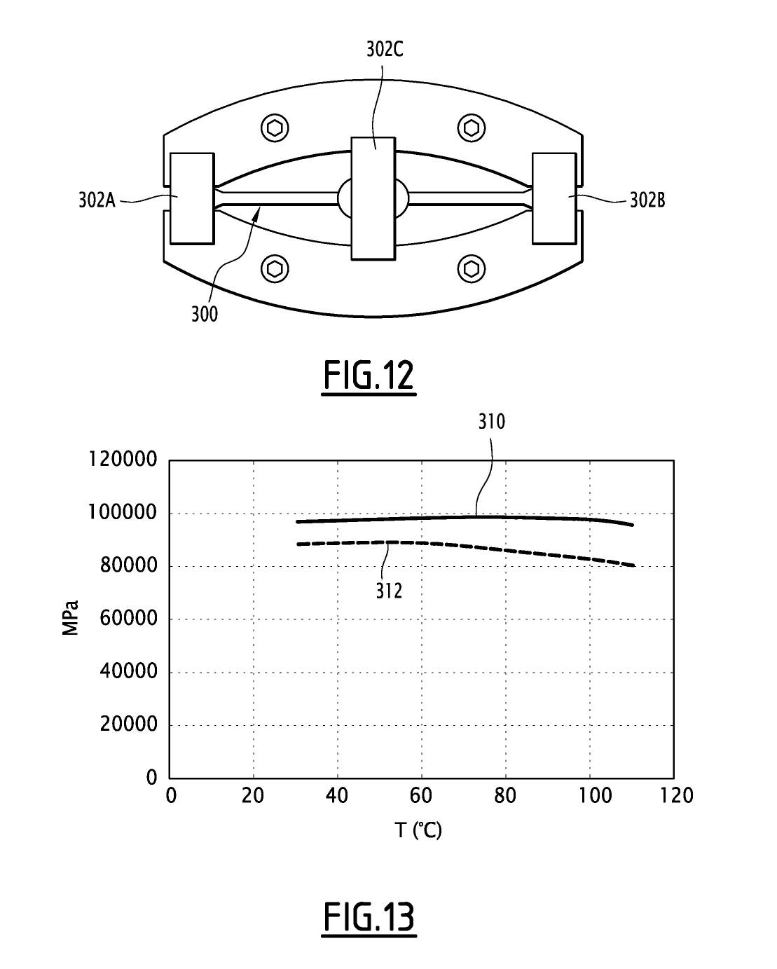

FIG. 12 is a top view of a device for mechanical characterization of products containing an elongate material according to the invention; and

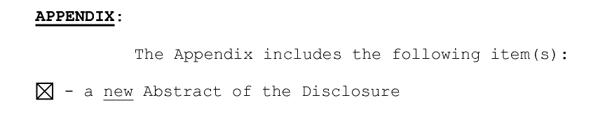

FIG. 13 is a graph comparing the mechanical behavior of a product containing an elongate material according to the invention with a product having no elongate material according to the invention.

FIGS. 1 to 6 show a first installation 10 for the preparation of a product 12 provided with carbon nanostructures according to the invention, the product 12 being visible in FIGS. 10 and 11.

As illustrated by FIGS. 10 and 11, the product 12 includes an elongate material 14, on which carbon nanostructures 16 are grafted.

The elongate material 14 is for example formed with a base of individual macroscopic fibers 18, the carbon nanostructures 16 being grafted on the fibers.

Examples of macroscopic fibers are ceramic fibers, such as silica fibers, in particular glass fibers, carbon fibers, basalt fibers, organic fibers, in particular organic fibers with high temperature resistance such as aramid fibers, in particular meta-aramid fibers such as poly(m-phenyleneisophthalamide) (NOMEX®) or poly(p-phenylene terephthalamide) (KEVLAR®) fibers, fluorinated polymer fibers, in particular polytetrafluoroethylene (TEFLON®), polyazole fibers, such as poly(p-phenylene-2,6-benzobisoxazole), polysulfide fibers, such as poly(phenylene sulfide) (PPS), imidazole fibers such as poly(benzimidazole) (ZYLON®), oxidized acrylic fibers (LASTAN®).

Advantageously, other organic fibers with a moderate temperature resistance can form the elongate material 14.

Within the meaning of the present invention, a fiber is an elongate material having a length significantly greater than its maximum transverse dimension. The minimum transverse dimension of a macroscopic fiber is for example greater than 5 μm.

The elongate material 14 is for example in the form of an individual fiber, or an assembly of fibers forming a thread, ribbon, strand or lock.

The elongate material 14 may also be obtained from an assembly of woven, braided, knit fibers, or a nonwoven. It may form a ply, or a web of fibers.

The elongate material 14 has a length significantly greater than its other dimensions, for example greater than 1 cm, in particular greater than 10 cm.

Advantageously, the elongate material 14 is able to be wound on a rotating storage member such as a drum or spool, or to be unwound from such a member.

In another alternative, the elongate material 14 is formed from a non-fibrous solid, such as a solid matrix. It for example forms a film.

The carbon nanostructures 16 grafted on the elongate material are for example carbon nanofibers or carbon nanotubes.

The term “carbon nanofibers” generally refers to a solid cylindrical nanostructure formed by stacked layers of graphene, the layers for example assuming the form of cones, or a plate.

The nanofibers have at least one dimension on the nanometric scale, i.e., smaller than a micrometer.

In the example shown in the figures, the nanofibers thus have a transverse dimension smaller than 100 nm, in particular smaller than 50 nm, and for example comprised between 15 and 20 nm. They have a length smaller than 1 mm, in particular smaller than 100 μm, for example comprised between 20 and 30 μm.

A “nanostructure” refers to a particular crystalline structure with a hollow tubular shape, made up of atoms advantageously arranged regularly in a pentagon, hexagon or heptagon defining a hollow central passage.

The nanotubes are produced from carbon atoms to form carbon nanotubes.

The nanotubes have at least one dimension on the nanometric scale, i.e., smaller than a micrometer.

In the example illustrated in the figures, the nanotubes thus have a transverse dimension smaller than 100 nm, in particular smaller than 50 nm and for example comprised between 15 and 20 nm. They have a length smaller than 1 mm, in particular smaller than 100 μm, for example comprised between 20 and 30 μm. The carbon nanotubes are in particular an allotropic carbon form.

In one embodiment, the nanotubes are single-walled nanotubes.

Advantageously, the nanotubes are multi-walled nanotubes with several graphene walls wound around one another, for example in concentric cylinders.

Owing to the implementation of the method according to the invention, the nanostructures 16 are grafted on the surface of the elongate material 14.

This grafting is for example done by a covalent chemical bond between the elongate material 14 and the atoms making up the nanostructures 16. Thus, the nanostructures 16 are fixed on the elongate material 14 and can be moved jointly with it. This grafting can be embodied by an anchoring of several nanometers of the nanostructures 16 to the surface of the elongate material 14.

In the example shown in FIGS. 10 and 11, the nanostructures 16 form a web around the elongate material 14, each nanostructure 16 being fixed to the first point on the elongate material 14 or on another nanostructures 16. Each nanostructure 16 further has a free end or an end that is connected to another nanostructures 16.

The surface density of nanostructures 16 grafted on the elongate material 14 is advantageously greater than 0.01 mg of nanostructures per square centimeter and is for example comprised between 0.01 mg/cm² and 5 mg/cm² of nanostructure 16.

Thus, the nanostructures 16 modify the properties of the elongate material 14, for example to increase the conductivity of the elongate material 14 or its mechanical strength.

As illustrated by FIGS. 1 to 6, the preparation installation 10 according to the invention includes a device 20 for grafting nanostructures 16 on the elongate material 14, and an assembly 22 for continuous advancement of the elongate material 14 in the grafting device 20.

Advantageously, the installation 10 further includes an assembly 24 for pretreating the elongate material 14 before it passes in the grafting device 20.

The grafting device 20 is illustrated by FIG. 2. According to the invention, it includes a torch 26 generating a flame 28 in an ambient air volume 30, an assembly 32 for conveying gas to the torch 26 to feed the flame 28, and a cooling support 33 positioned below the torch 26.

The grafting device 20 further includes a control and regulating unit 34.

As illustrated by FIGS. 2, 4 and 5, the torch 26 advantageously extends along the vertical axis A-A′. It comprises a body 40 defining at least one channel 42 for conveying a gas mixture.

In the example shown in FIGS. 2 and 5, the torch 22 defines a single central gas injection channel 42. The channel 42 is connected upstream to the gas conveying assembly 32. It emerges downstream through a downstream opening 46 extending across from the receiving assembly 32.

The channel 42 here extends along the axis A-A′, at the center of the torch 22.

In the alternative shown in FIG. 6, the torch 22 defines a plurality of peripheral auxiliary channels 44 for the injection of a cooling gas.

The channels 44 are positioned around the central channel 42. Each auxiliary channel 44 has a section smaller than that of the central channel 42.

The auxiliary channel 44 is connected upstream to the gas conveying assembly 32.

The flame 28 is created at the outlet of and below the torch 26, across from the opening 46. It has a substantially frustoconical profile diverging away from the torch 22 while being distributed on the cooling support 33.

The gas conveying assembly 32 includes at least one combustible gas source 50, at least one oxidizing gas source 52, a conduit 54 for conveying the combustible gas from the source 50 to the torch 22 and a conduit 56 for conveying the oxidizing gas from the source 52 to the torch 22.

Advantageously, the conveying assembly 32 further includes a first combustible gas regulator 58 and a second oxidizing gas regulator 60.

The combustible gas present in the source 50 contains atoms designed to form the carbon nanostructures. The combustible gas for example contains a hydrocarbon. It comprises or is advantageously made up of acetylene. The combustible gas source 50 therefore contains acetylene, either pure or in a mixture.

The oxidizing gas contained in the source 52 is for example oxygen, either pure or in a mixture.

The conduits 54, 56 respectively connect each respective source 50, 52 to the channel 42. A mixer can be interposed between the sources 50, 52 and the torch 22 to mix the gases coming from the conduits 54, 56 before its insertion into the channel 42.

Each regulator 58, 60 is able to regulate the gas flow rate flowing in the conduit 54, 56 on which it is mounted. The regulators 58, 60 are connected to the control unit 34.

For the implementation of the method according to the invention, the regulators 58, 60 are advantageously able to maintain a ratio of volume flow rate of combustible gas to volume flow rate of oxidizing gas comprised between 1.2 and 1.5, advantageously between 1.25 and 1.30.

In this example, the regulators 58, 60 are further able to keep the total volume flow rate of gas below 1 liter/minute, and for example comprised between 0.2 liters/minute and 0.8 liters/minute, in particular between 0.4 liters/minute and 0.5 liters/minute.

In the alternative illustrated in FIG. 6, the conveying assembly 32 further includes a source of cooling gas 62, and an intake conduit 64 for the cooling gas into each of the auxiliary channels 44. The conduit 64 is provided with a cooling gas regulator 68.

The cooling gas is for example argon or helium.

In the example illustrated by FIG. 2, the cooling support 33 includes a lower base part 70 and an upper opposite part 72, the elongate material 14 being designed to flow in the flame 28 between the lower part 70 and the upper part 72.

The cooling support 33 further includes a heat regulating assembly 74 able to cool the lower part 70 and/or the upper part 72 in a controlled manner.

The lower part 70 includes a substrate 76 designed to come into contact with the elongated material 14 and a heat regulating block 78 positioned below the substrate 76.

The substrate 76 is advantageously made from a flat metal plate. It defines an upper bearing surface 80 for the elongate material 14 extending transversely relative to the axis A-A′, across from the torch 26.

The upper part 72 is positioned axially between the torch 26 and the lower part 70.

It includes an upper body 82 which, in this example, is in the shape of a staple. The upper body 82 delimits an inner surface 84 placed across from the upper bearing surface 80 of the elongate material 14, and an inclined upper surface 86 to deflect the flame 28 toward the elongate material 14.

The upper body 82 defines, in the upper surface 86, a central notch 88 for passage of the elongate material 14.

In this example, the lower surface 84 is substantially parallel to the upper bearing surface 80.

The inclined surface 86 has a nonzero incline, and less than 90° relative to the upper surface 80, projected a plane passing through the axis A-A′.

The incline angle α of the inclined surface 86 relative to the upper surface 80 is thus comprised between 20° and 60° to ensure effective deflection of a lateral part of the flame 28.

The notch 88 has a curved shape corresponding to a part of the contour of the flame 28.

Thus, the upper part 72 is able to ensure pressing of the elongate material 14 against the upper surface 80, the cooling of the active zone of flame 28, and its optimal orientation, so as to perform a treatment that is as effective as possible of the elongate material 14 from the carbon precursor-rich zone in the flame 28.

The heat regulating assembly 74 includes a refrigerant fluid source 90, a first conduit 92 for the flow of refrigerant through the lower part 70, and a second conduit 94 for the flow of refrigerant through the upper part 72.

The assembly 74 further comprises a temperature sensor 96, for example a parameter, able to measure the temperature of the region of the flame 28 across from a point of contact of the elongate material 14 with the upper surface 80, in the vicinity of the lower part 70.

The refrigerant fluid is able to discharge the heat generated by the flame 28 by contactless heat exchange. It is for example made up of water, a mixture of water with another refrigerant such as glycol, or carbon dioxide.

The control unit 34 is able to control the gas conveying assembly 32 to provide an appropriate mixture of combustible gas and oxidizing gas, optionally with refrigerant gas.

The unit 34 is also able to command the heat regulating assembly 74 to maintain the temperature of the flame, at a point of contact between the elongate material 14 and the upper surface 80, as measured by the sensor 96, according to a setpoint temperature for example comprised between 400° C. and 700° C., in particular between 500° C. and 700° C.

According to the invention, the torch 26, the flame 28 and the cooling support 33 are placed in a volume of ambient air, for example in a building, without being placed in a confinement enclosure in which a particular atmosphere is defined.

In particular, the volume content of oxygen in the volume of ambient air is greater than 19%, and is in particular comprised between 20% and 22%.

The volume content of nitrogen in the volume of ambient air is greater than 70%, and is in particular comprised between 75% and 80%. The preparation method according to the invention can therefore be implemented very simply, without providing a confinement enclosure in which a particular atmosphere must be controlled. The atmosphere prevailing around the torch 26, and in particular between the torch 26 and the cooling support 33 around the flame 28, is not controlled.

In reference to FIG. 1, the advancement assembly 22 includes an upstream element 100 for withdrawing the raw elongate material 14, before it passes in the grafting device 20, a mechanism (not shown) for guiding the elongate material 14 through the grafting device 20, and a downstream element 102 for storing the elongate material 14 provided with grafted carbon nanostructures 16, coming from the grafting device 20.

The upstream element 100 for example includes an upstream member for winding the raw elongate material 14. The raw elongate material 14 can be withdrawn from the upstream element 100 continuously.

The mechanism for guiding the elongate material 14 is able to guide the material 14 in the grafting device 20, to apply it on the surface 80 and position it in the flame 28 across from the inclined surface 86 of the upper part 72. It includes means for adjusting the position of the elongate material 14 relative to the upper surface 80 and relative to the inclined surface 86 that can be controlled by the control unit 34.

The downstream element 102 for example includes a downstream member for winding the grafted elongate material 14. The grafted elongate material 14 is able to be stored in the downstream element 102 continuously.

Furthermore, the downstream element 102 and/or the guide mechanism include means for driving the elongate material 14 at a given speed in the grafting device 20. The given speed is for example greater than 1 mm/min, and is in particular greater than 5 mm/min. This speed is advantageously greater than 300 mm/min and is for example comprised between 300 mm/min and 10,000 mm/min.

The pretreatment assembly 24 is positioned between the upstream withdrawal element 100 and the grafting device 20. It includes a device 110 for applying a catalytic agent able to initiate the growth of carbon nanostructures on the outer surface of the raw elongate material 14. The catalytic agent is for example formed from a metal such as iron, nickel, or cobalt. It is deposited in the form of a plurality of sites able to cause the growth of carbon nanostructures 16 on the surface of the elongate material 14.

Advantageously, the device 110 includes means 112 for dipping the elongate material 14 in a diluted solution containing a metal, and drying means 114.

A method for preparing the product 12 according to the invention using the installation 10 will now be described.

Initially, the grafting device 20 is provided and is positioned in a volume of ambient air.

Raw elongate material 14 is positioned in the upstream withdrawal assembly 100 and is deployed to the pretreatment assembly 24, when it is present, through the grafting device 20, up to the downstream storage element 102.

Then, the grafting device 20 is activated. To that end, the heat regulating assembly 74 is started up to cause the cooling of the lower part 70 and the upper part 72 of the cooling support 33.

Furthermore, a mixture of oxidizing gas and combustible gas is provided in the torch 26 to ignite and feed the flame 28.

The temperature sensor 96 is further activated to adjust the temperature of the flame 28.

The control unit 34 controls the volume ratio of the combustible gas to the oxidizing gas to advantageously keep it between 1.1 and 1.4, in particular between 1.25 and 1.3.

The total volume of combustible gas and oxidizing gas is greater than 0.3 l/min and is in particular comprised between 0.4 l/min and 0.5 l/min.

The flame 28 is created in a volume of ambient air, without it being necessary to create a particular atmosphere around the torch 26, which is particularly easy to use.

Once the flame 28 is stabilized, the position of the upper surface 80 and the lower part 70 is adjusted to ensure that a temperature comprised between 400° C. and 700° C., advantageously between 500° C. and 700° C., is present in the zone of the flame 28 in which the elongate material 14 will travel.

Thus, the axial distance separating the free end of the torch 26 from the surface 80 is for example comprised between 3 mm and 5 mm, in particular between 4 mm and 4.5 mm.

That being done, the elongate material 14, for example a carbon thread, is driven to advance continuously between the upstream withdrawal element 100 and the downstream storage element 102, through the pretreatment assembly 24 and the grafting device 20.

During the passage in the pretreatment assembly 24, the raw elongate material 14 is provided with metal grafting sites on its outer surface. Advantageously, it is dipped in a metal solution provided in the dipping means 112, then it dries in the drying means 114.

The elongate material 14 next passes in the grafting device 20. It is pressed against the upper surface 80 and penetrates the flame 28. As illustrated by FIG. 4, it passes across from the inclined surface 86 of the upper part 70.

The flame 28 being projected against the surface 86, it has a main segment 120, upstream from contact with the inclined surface 86, and a segment 122 deflected off the surface 86, in which the elongate material 14 travels.

If necessary, a cooling gas, such as argon, is added to the flame 28.

Thus, the elongate material 14 is subjected to part of the flame 28 that has a controlled temperature, and the cooling of which is controlled.

In this example, the elongate material 14 travels continuously in the flame 28 at a speed comprised between 300 mm/min and 6000 mm/min.

This passage causes the continuous grafting of carbon nanostructures 16 on the elongate material 14, on the surface of the elongate material 14 placed across from the flame 28.

The length of the nanostructures 16 is for example greater than 10 μm, and in particular comprised between 20 μm and 30 μm. The maximum diameter of the nanostructures 16 is for example less than 1 μm, and is in particular less than 50 nm.

The elongate material 14, provided with carbon nanostructures 16, is next stored in the downstream assembly 102, continuously.

The method according to the invention is therefore particularly easy to implement, while allowing optimal productivity. It allows effective grafting of carbon nanostructures on various elongate materials, such as fibers, threads, structured matrices, webs, etc.

This method is also very safe for operators, since it involves grafting of nanostructures 16 on the elongate material 14.

The grafting is done continuously, as the elongate material 14 advances through the flame 28.

The obtained products 12 are for example shown in FIGS. 11 and 12.

In a first alternative installation 10 shown in FIGS. 7 and 8, an elongate material 14 in the form of a strip 130 is inserted into the grafting device 20.

The upper surface 80 of the lower part 70 of the support has a curved shape, convex toward the torch 26, with the exception of a planar segment 132 situated across from the upper part 72 and the flame 28.

The upstream assembly 100 and the downstream assembly 102 each comprise a spool. The spool of the upstream assembly 100 is able to unwind the raw elongate material 14, the spool of the downstream assembly 102 being able to unwind the elongate material 14 provided with nanostructures 16.

In a second alternative installation 10 shown in FIG. 9, the installation 10 includes a first upstream grafting device 20A for an upper part of the elongate material 14 and a second downstream grafting device 20B for a lower part of the elongate material 14.

The first grafting device 20A is oriented opposite the second grafting device 20B.

Thus, the torch 26 of the first grafting device 20A opens in a first direction (downward in FIG. 9) toward the cooling support 33 of the device 20A.

The torch 26 of the second grafting device 20B opens opposite the first direction in a second direction (upward in FIG. 9) across from the cooling support 33 of that device 20B.

Thus, when the elongate material 14 passes through the first grafting device 20A, a first part of the outer surface 14 of that material is provided with nanostructures 16.

Then, when the elongate material 14 passes through the second heating device 20B, a second part of the outer surface 14 of that material 14 that was in contact with the upper surface 80 of the cooling assembly 33 of the first grafting device 20A is in turn provided with nanostructures 16.

The invention described above makes it possible to obtain elongate materials 14 provided with grafted carbon nanostructures 14 that are usable in many technical fields, for example reinforcing matrices made from polymer materials, obtaining structural composite materials to obtain high-performance composite parts (for example for aeronautics, sports and recreation, railroad use, the automobile industry), or the development of smart materials (filtration, smart textiles, fuel cells).

In one example embodiment, an elongate material 14 formed by carbon threads has been provided with carbon nanostructures 16 made up of nanotubes, using a method according to the invention.

The modified carbon threads have been molded by manual stratification using a 2025 epoxy resin by the company AXON.

Composite bars made from carbon threads of type T300 by the company TORAY having a length of 80 mm, a width of 2 mm, a thickness of 1 mm, with an allowance of plus or minus 0.06 mm have been obtained by embedding four modified carbon threads in the resin.

As a comparison, test pieces containing raw carbon threads, not treated using the method according to the invention, have been molded.

The electric resistance of the test pieces comprising threads treated using the method according to the invention is below 30 ohms, while the samples comprising untreated threads have an electric resistance of close to 235 ohms.

These composite bars 300 were biased using dynamic sinusoidal movement in a triple-flex pattern (embedded at the ends 302A, 302B and at the center 302C) to perform a dynamic thermomechanical analysis (DTMA). The distance between supports was 60 mm, the frequency was 5 Hz, the speed of temperature rise 2° C./min and a travel of ±10 μm. The tests were conducted between 25° C. and 110° C., before the vitreous transition of the resin. A top view of the assembly is shown in FIG. 11.

FIG. 12 shows the evolution of the storage module E′ as a function of temperature. The composite bars on which nanostructures 16 are grafted on carbon fibers have a storage module 310 that is 10% greater than the storage module 312 of the reference bar.

Relative to the methods of the state of the art, the inventive method is therefore particularly simple to implement, since it does not require inserting the particles in a furnace, or adjusting a particular atmosphere in the furnace. The method can be implemented simply and practically, directly in a volume of ambient air. The obtained nanotube growth is then fast, unlike that of the methods of the state of the art, in particular that described in Shaffer et al., Carbon, 48, 277-286, 2010, which makes it possible to obtain high outputs.

Furthermore, the inventors have discovered particularly surprisingly that the flame methods used in the state of the art to produce free carbon nanostructures (for example, see US 2011/0059006 and US 2010/0119724) could, in the presence of an elongate material passing in the flame, lead to the grafting of nanostructures on the elongate material. The method according to the invention makes it possible to fix the nanostructures on the elongate material to produce a modified elongate material having improved properties. The elongate products thus obtained are usable in particular to be embedded in a wide variety of polymer matrices to improve the properties of the matrix.

The method according to the invention comprises the continuous advancement of the elongate material through the flame, in a volume of open air, which guarantees rapid and effective grafting of a considerable length of the elongate material. The method therefore does not require immobilizing the test pieces to be treated for a significant length of time in a confined atmosphere (as in the EP 2,224,830, in Yoon et al., Science of the Total Environment, 409, 4132-4138, 2011, or in Shaffer et al., Carbon, 48, 277-286, 2010) or immobilizing the samples to be treated in a flame (see Amini et al., Carbon, 48, 3131-3138, 2010 or Mai et al., Carbon, 50, 2347-2374, 2012).

The method according to the invention also avoids providing complex interfaces with the CVD furnace, when the material is introduced continuously into such a furnace as in EP 2,290,139.

1-14. (canceled)

15. A method for preparing an elongate material with grafted carbon nanostructures, comprising the following steps:
providing a grafting device comprising a torch producing a flame in an ambient air volume, and a cooling medium positioned across from the flames;
continuously advancing the elongated material through the flame between the torch and the cooling support; and
continuously grafting carbon nanostructures on the elongate material as it advances through the flame.

16. The method according to claim 15, wherein the continuous advancement of the elongate material includes withdrawing of the raw elongate material outside an upstream withdrawal assembly, passing of the withdrawn raw elongate material through the flame, then storing of the elongate material by the carbon nanostructures on a downstream storage assembly.

17. The method according to claim 15, including passing the elongate material between a base part of the cooling support and a part opposite the cooling support positioned between the base part and the torch, the base part and the opposite part each being cooled.

18. The method according to claim 17, wherein the elongate material is pressed against the base part in the flame during its continuous advancement through the flame.

19. The method according to claim 15, wherein the cooling support includes at least one inclined surface for deflecting at least one main segment of the flame produced by the torch, the flame produced by the torch comprising a deflected segment situated downstream from the inclined deflection surface, the elongate material passing through the deflected segment.

20. The method according to claim 15, wherein the temperature of the region of the flame in which the elongate material passes is below 700° C.

21. The method according to claim 15, wherein the torch produces a flame created by the combustion of a hydrocarbon power gas with oxygen.

22. The method according to claim 15, including depositing on the surface of the elongate material a catalytic agent able to initiate the growth of carbon nanostructures.

23. The method according to claim 15, wherein the speed of advancement of the elongate material in the flame is greater than 1 m/min.

24. An installation for preparing an elongate material provided with grafted carbon nanostructures, comprising:
a grafting device comprising a torch producing a flame in a volume of ambient air, the grafting device including a cooling support positioned across from the flame;
an assembly for continuous advancement of the elongate material through the flame between the torch and the cooling support;
the grafting device being able to continuously graft carbon nanostructures on the elongate material as it advances through the flame.

25. The installation according to claim 24, wherein the assembly for continuous advancement of the elongate material includes an upstream assembly for withdrawal of the raw elongate material, a mechanism for passing the withdrawn raw elongate material through the flame, and a downstream assembly for storage of the elongate material provided with carbon nanostructures.

26. The installation according to claim 25, wherein the cooling support includes a base part and an opposite part positioned between the base part and the torch, the base part and the opposite part each being cooled, the advancement assembly being able to guide the elongate material between the base part and the opposite part.

27. The installation according to claim 25, wherein the cooling support includes at least one inclined deflection surface for at least one main segment of the flame produced by the torch, the flame produced by the torch comprising a deflected segment situated downstream from the inclined deflection surface, the advancement assembly being able to guide the elongate material so that it passes through the deflected segment.

28. A product comprising an elongate material provided with grafted carbon nanostructures, in particular carbon nanotubes and/or carbon nanofibers, obtainable using the method according to claim 15.

29. The method according to claim 20, wherein said temperature is comprised between 400° C. and 700° C.

30. The method according to claim 21, wherein the power gas is acetylene.

31. The method according to claim 21, wherein the ratio of the flow of power gas to the flow of oxygen provided in the torch advantageously being greater than 1.

32. The method according to claim 22, wherein the catalytic agent is advantageously being deposited from a diluted metal solution.
